(19) United States
(12) Patent Application Publication
(10) Pub. No.: US 2008/0062610 A1
(43) Pub. Date: Mar. 13, 2008

(54) ELECTROSTATIC CHUCK DEVICE

(76) Inventors: Shinji HIMORI, Nirasaki-shi (JP); Shoichiro MATSUYAMA, Nirasaki-shi (JP); Atsushi MATSUURA, Nirasaki-shi (JP); Hiroshi INAZUMACHI, Funabashi-shi (JP); Mamoru KOSAKAI, Narashino-shi (JP); Yukio MIURA, Funabashi-shi (JP); Keigo MAKI, Ichikawa-shi (JP)

Correspondence Address: OSTROLENK FABER GERB & SOFFEN, 1180 AVENUE OF THE AMERICAS, NEW YORK, NY, 100368403, US

(21) Appl. No.: 11/835,560

(22) Filed: Aug. 8, 2007

Related U.S. Application Data
(60) Provisional application No. 60/828,408, filed on Oct. 6, 2006.

(30) Foreign Application Priority Data
Aug. 10, 2006 (JP) 2006-218445

(51) Int. Cl. H01L 21/683

(52) U.S. Cl. 361/234

(57) ABSTRACT

An electrostatic chuck device includes: an electrostatic chuck section including a substrate, which has a main surface serving as a mounting surface on which a plate-like sample is mounted and an electrostatic-adsorption inner electrode built therein, and a power supply terminal for applying a DC voltage to the electrostatic-adsorption inner electrode; and a metal base section that is fixed to the other main surface of the electrostatic chuck section so as to be incorporated into a body and that serves as a high frequency generating electrode. Here, the volume resistivity of the electrostatic-adsorption inner electrode is in the range of 1.0×10⁻¹Ωcm to 1.0×10⁸ Ωcm.

### BACKGROUND OF THE INVENTION

1. Field of the Invention

The present invention relates to an electrostatic chuck device, and more particularly, to an electrostatic chuck device suitable for use in a high-frequency discharge type plasma processing apparatus for applying a high-frequency voltage to an electrode to generate plasma and processing a plate-like sample such as a semiconductor wafer, a metal wafer, and a glass plate by the use of the generated plasma.

Priority is claimed on Japanese Application No. 2006-218445, filed Aug. 10, 2006, which is incorporated herein by reference. This application also claims the benefit pursuant to 35 U.S.C. §102(e) of U.S. Provisional Application No. 60/828,408, filed on Oct. 6, 2006.

2. Description of the Related Art

Conventionally, plasma was often used in processes such as etching, deposition, oxidation, and sputtering for manufacturing semiconductor devices such as IC, LSI, and VLSI or flat panel displays (FPD) such as a liquid crystal display, in order to allow a process gas to react sufficiently at a relatively low temperature. In general, methods of generating plasma in plasma processing apparatuses are roughly classified into a method using glow discharge or high-frequency discharge and a method using microwaves.

FIG. 9 is a sectional view illustrating an example of an electrostatic chuck device 1 mounted on a known high-frequency discharge type plasma processing apparatus. The electrostatic chuck device 1 is disposed in a lower portion of a chamber (not shown) also serving as a vacuum vessel and includes an electrostatic chuck section 2 and a metal base section 3 fixed to the bottom surface of the electrostatic chuck section 2 so as to be incorporated into a body.

The electrostatic chuck section 2 includes: a substrate 4, which has a top surface serving as a mounting surface 4a, on which a plate-like sample W such as a semiconductor wafer is disposed, so as to adsorb the plate-like sample W in an electrostatic manner, and an electrostatic-adsorption inner electrode 5 built therein; and a power supply terminal 6 for applying a DC voltage to the electrostatic-adsorption inner electrode 5. A high DC voltage source 7 is connected to the power supply terminal 6. The metal base section 3, which is also used as a high-frequency generating electrode (lower electrode), is connected to a high-frequency voltage generating source 8 and has a flow passage 9 for circulating a cooling medium such as water or an organic solvent formed therein. The chamber is grounded.

The electrostatic chuck device 1 adsorbs the plate-like sample W, by placing the plate-like sample W on the mounting surface 4a and allowing the high DC voltage source 7 to apply a DC voltage to the electrostatic-adsorption inner electrode 5 through the power supply terminal 6. Subsequently, a vacuum is generated in the chamber and a process gas is introduced thereto. Then, by allowing the high-frequency voltage generating source 8 to apply high-frequency power across the metal base section 3 (lower electrode) and an upper electrode (not shown), a high-frequency electric field is generated in the chamber. Frequencies of several tens of MHz or less are generally used as the high frequency.

The high-frequency electric field accelerates electrons, plasma is generated due to ionization by collision of the electrons with the process gas, and a variety of processes can be performed by the use of the generated plasma.

In the recent plasma processes, there is an increased need for processes using “low-energy and high-density plasma” having low ion energy and high electron density. In the processes using the low-energy and high-density plasma, the frequency of the high-frequency power for generating plasma might increase greatly, for example, to 100 MHz.

In this way, when the frequency of the power to be applied increases, the electric field strength tends to increase in a region corresponding to the center of the electrostatic chuck section 2, that is, the center of the plate-like sample W, and to decrease in the peripheral region thereof. Accordingly, when the distribution of the electric field strength is not even, the electron density of the generated plasma is not even and thus the processing rate varies depending on in-plane positions in the plate-like sample W. Therefore, there is a problem in that it is not possible to obtain a processing result excellent in in-plane uniformity.

A plasma processing apparatus shown in FIG. 10 has been suggested to solve such a problem (see Patent Literature 1).

In the plasma processing apparatus 11, in order to improve the in-plane uniformity of the plasma process, a dielectric layer 14 made of ceramics or the like is buried at the central portion on the surface of the lower electrode (metal base section) 12 supplied with the high-frequency power and opposed to the upper electrode 13, thereby making the distribution of the electric field strength even. In the figure, reference numeral 15 denotes a high frequency generating power source, PZ denotes plasma, E denotes electric field strength, and W denotes the plate-like sample.

In the plasma processing apparatus 11, when the high frequency generating power source 15 applies the high-frequency power to the lower electrode 12, high-frequency current having been transmitted on the surface of the lower electrode 12 and having reached the top due to a skin effect flows toward the center along the surface of the plate-like sample W, and a part thereof leaks toward the lower electrode 12 and then flows outward inside the lower electrode 12. In this course, the high-frequency current is submerged deeper in the region provided with the dielectric layer 14 than the region not provided with the dielectric layer 14, thereby generating hollow cylindrical resonance of a TM mode. As a result, the electric field strength of the central portion supplied to the plasma from the surface of the plate-like sample W is weakened and thus the in-plane electric field of the plate-like sample W is made to be uniform.

The plasma process is often performed under depressurized conditions close to a vacuum. In this case, an electrostatic chuck device shown in FIG. 11 is often used to fix the plate-like sample W.

The electrostatic chuck device 16 has a structure such that a conductive electrostatic-adsorption inner electrode 18 is built in a dielectric layer 17. For example, the conductive electrostatic inner electrode is interposed between two dielectric layers formed by thermally spraying alumina or the like.

The electrostatic chuck device 16 adsorbs and fixes the plate-like sample W by the use of the electrostatic adsorption force generated on the surface of the dielectric layer 17 by allowing the high DC voltage source 7 to apply the high DC power to the electrostatic-adsorption inner electrode 18.

[Patent Literature 1] Japanese Patent Unexamined Publication No. 2004-363552 (see paragraphs 0084 and 0085 of page 15 and FIG. 19) In the known plasma processing apparatus 11 described above, when the electrostatic chuck device 16 processes the plate-like sample W by the use of the plasma in a state where it is disposed on the lower electrode 12, the high-frequency current does not pass through the electrostatic-adsorption inner electrode 18 of the electrostatic chuck device 16 and thus a flow of current directed to the outside from the electrostatic-adsorption inner electrode 18 is generated.

In other words, since the electrostatic-adsorption inner electrode 18 is disposed in the electrostatic chuck device 16, the dielectric layer 14 is not viewed from the plasma PZ and thus an effect of lowering the potential of the plasma in the region in which the dielectric layer 14 is buried cannot be exhibited.

As a result, the potential of the plasma above the central portion of the plate-like sample W is high and the potential above the peripheral portion is low, thereby making the processing rate different between the central portion and the peripheral portion of the plate-like sample W. Accordingly, this is a reason for in-plane nonuniformity of the plasma process such as etching.

### SUMMARY OF THE INVENTION

The invention is made to solve the above-mentioned problems. An object of the invention is to provide an electrostatic chuck device which can enhance in-plane uniformity of the electric field strength in plasma and can perform a plasma process with high in-plane uniformity on a plate-like sample, when it is applied to a plasma processing apparatus.

As a result of keen studies for accomplishing the above-mentioned object, the inventors found that the above-mentioned object could be efficiently accomplished by setting the volume resistivity of the electrostatic-adsorption inner electrode within the range of 1.0×10⁻¹ Ωcm to 1.0×10⁸ Ωcm, and thus completed the invention.

That is, according to an aspect of the invention, there is provided an electrostatic chuck device including: an electrostatic chuck section including a substrate, which has a main surface serving as a mounting surface on which a plate-like sample is mounted and an electrostatic-adsorption inner electrode built therein, and a power supply terminal for applying a DC voltage to the electrostatic-adsorption inner electrode; and a metal base section that is fixed to the other main surface of the substrate of the electrostatic chuck section so as to be incorporated into a body and that serves as a high frequency generating electrode. Here, the volume resistivity of the electrostatic-adsorption inner electrode is in the range of 1.0×10⁻¹ Ωcm to 1.0×10⁸ Ωcm.

In the electrostatic chuck device, it is preferable that a concave portion be formed in the main surface of the metal base section facing the electrostatic chuck section, a dielectric plate be fixed to the concave portion, and the dielectric plate and the electrostatic chuck section be adhesively bonded to each other with an insulating adhesive bonding layer interposed therebetween.

In the electrostatic chuck device, it is preferable that the thickness of the dielectric plate decrease from the center to the peripheral edge.

In the electrostatic chuck device, it is preferable that a concave portion be formed in the main surface of the metal base section facing the electrostatic chuck section and the substrate of the electrostatic chuck section be fixed to the concave portion.

In the electrostatic chuck device, it is preferable that the thickness of the substrate of the electrostatic chuck section decrease from the center to the peripheral edge.

In the electrostatic chuck device according to the invention, the volume resistivity of the electrostatic-adsorption inner electrode is set to the range of 1.0×10⁻¹ Ωcm to 1.0×10⁸ Ωcm. Accordingly, when a high-frequency power is applied to the metal base section, a high-frequency current can pass through the electrostatic-adsorption inner electrode and thus the electric field strength on the surface of the electrostatic chuck section can be made uniform. Therefore, it is possible to make the plasma density even.

As described above, when the concave portion is formed in the main surface of the metal base section facing the electrostatic chuck section, the dielectric plate is fixed to the concave portion, and the dielectric plate and the electrostatic chuck section are adhesively bonded to each other with an insulating adhesive bonding layer interposed therebetween, a high-frequency current can flow through the adhesive bonding layer. Accordingly, by fixing the dielectric plate to the concave portion, it is possible to reduce the electric field strength at the center of the electrostatic chuck section and thus to make more uniform the electric field strength on the surface of the electrostatic chuck section when a high-frequency voltage is applied to the metal base section. As a result, it is possible to further make the plasma density even.

As described above, when the thickness of the dielectric plate decreases from the center to the peripheral edge thereof, it is possible to further reduce the electric field strength at the center of the electrostatic chuck section and thus to make more uniform the electric field strength on the surface of the electrostatic chuck section when a high-frequency voltage is applied to the metal base section. As a result, it is possible to further make the plasma density even.

As described above, when the concave portion is formed in the main surface of the metal base section facing the electrostatic chuck section and the substrate of the electrostatic chuck section is fixed to the concave portion, it is possible to omit the adhesive bonding layer between the electrostatic chuck section and the metal base section, thereby enhancing the thermal conductivity between the plate-like sample and the metal base section.

Since the substrate of the electrostatic chuck section is fixed to the concave portion of the metal base section, it is possible to easily position and fix the metal base section and the electrostatic chuck section relative to each other.

As described above, when the thickness of the substrate of the electrostatic chuck section decreases from the center to the peripheral edge, it is possible to further reduce the electric field strength at the center of the electrostatic chuck section and thus to make more uniform the electric field strength on the surface of the electrostatic chuck section when a high-frequency voltage is applied to the metal base section. As a result, it is possible to further make the plasma density even.

### BRIEF DESCRIPTION OF THE DRAWINGS

FIG. 1 is a sectional view illustrating an electrostatic chuck device according to a first embodiment of the invention.

FIG. 2 is a sectional view illustrating a modified example of a dielectric plate of the electrostatic chuck device according to the first embodiment of the invention.

FIG. 3 is a sectional view illustrating another modified example of a dielectric plate of the electrostatic chuck device according to the first embodiment of the invention.

FIG. 4 is a sectional view illustrating an electrostatic chuck device according to a second embodiment of the invention.

FIG. 5 is a sectional view illustrating a modified example of a substrate of an electrostatic chuck section of the electrostatic chuck device according to the second embodiment of the invention.

FIG. 6 is a sectional view illustrating another modified example of the substrate of the electrostatic chuck section of the electrostatic chuck device according to the second embodiment of the invention.

FIG. 7 is a diagram illustrating a measurement result of plasma uniformity in an example and Comparative Examples 1 and 2.

FIG. 8 is a diagram illustrating a measurement result of a variation with time of an electrostatic adsorption force in an example and Comparative Examples 1 and 2.

FIG. 9 is a sectional view illustrating an example of a known electrostatic chuck device.

FIG. 10 is a sectional view illustrating an example of a known plasma processing apparatus

FIG. 11 is a sectional view illustrating an example of a plasma processing apparatus mounted with the known electrostatic chuck device.

### DETAILED DESCRIPTION OF THE INVENTION

### First Embodiment

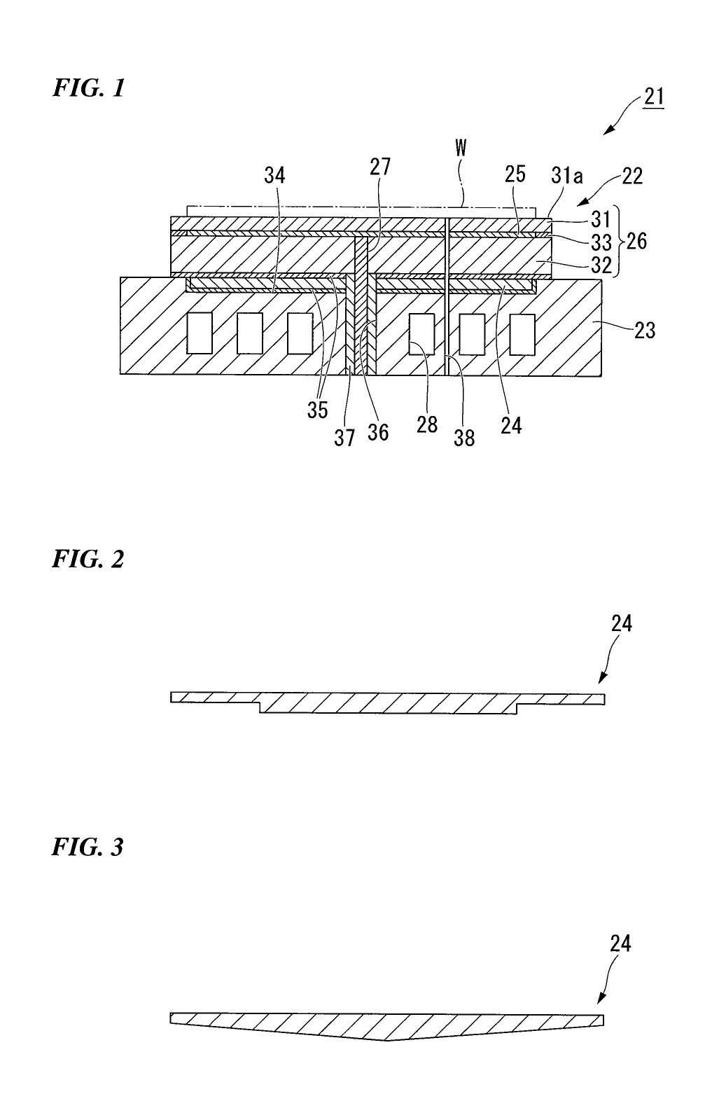

FIG. 1 is a cross-sectional view illustrating an electrostatic chuck device 21 according to a first embodiment of the invention. The electrostatic chuck device 21 includes an electrostatic chuck section 22, a metal base section 23, and a dielectric plate 24.

The electrostatic chuck section 22 includes a disc-like substrate 26, the top surface (one main surface) of which serves as a mounting surface for mounting a plate-like sample W and in which an electrostatic-adsorption inner electrode 25 is built, and a power supply terminal 27 for applying a DC voltage to the electrostatic-adsorption inner electrode 25.

The substrate 26 roughly includes a disc-like mounting plate 31 of which the top surface 3 la serves as the mounting surface for mounting the plate-like sample W such as a semiconductor wafer, a metal wafer, and a glass plate, a disc-like support plate 32 disposed opposite the bottom surface (the other main surface) of the mounting plate 31, the planar electrostatic-adsorption inner electrode 25 interposed between the mounting plate 31 and the support plate 32, and a ring-shaped insulating layer 33 disposed to surround the inner electrode 25.

The volume resistivity of the electrostatic-adsorption inner electrode 25 at the usage temperature of the electrostatic chuck device is in the range of 1.0×10⁻¹ Ωcm to 1.0×10⁸ Ωcm and preferably in the range of 1.0×10² Ωcm to 1.0×10⁴ Ωcm.

On the other hand, a flow passage 28 for circulating a cooling medium such as water or an organic solvent is formed in the metal base section 23 so as to maintain the plate-like sample W mounted on the mounting surface at a desired temperature. The metal base section 23 is also used as a high frequency generating electrode.

A circular concave portion 34 is formed in the surface (main surface) of the metal base section 23 facing the electrostatic chuck section 22 and the dielectric plate 24 is adhesively bonded to the concave portion 34 with an insulating adhesive bonding layer 35 or a conductive adhesive bonding layer interposed therebetween. The dielectric plate 24 and the support plate 32 of the electrostatic chuck section 22 are adhesively bonded to each other with the insulating adhesive bonding layer 35 interposed therebetween.

When the dielectric plate 24 and the support plate 32 of the electrostatic chuck section 22 are adhesively bonded to each other with a conductive adhesive bonding layer interposed therebetween, a high-frequency current is suppressed from flowing by the conductive adhesive bonding layer. Accordingly, the high-frequency current flows toward the peripheral edge through the conductive adhesive bonding layer, thereby not realizing a uniform plasma.

A power supply terminal insertion hole 36 is formed in the vicinity of the center of the support plate 32 and the metal base section 23, and the power supply terminal 27 for applying a DC voltage to the electrostatic-adsorption inner electrode 25 is inserted into the power supply terminal insertion hole 36 with a cylindrical insulator 37 interposed therebetween. The top end of the power supply terminal 27 is electrically connected to the electrostatic-adsorption inner electrode 25.

A cooling gas introduction hole 38 penetrating the mounting plate 31, the support plate 32, the electrostatic-adsorption inner electrode 25, and the metal base section 23 is formed therein and thus a cooling gas such as He is supplied to a gap between the mounting plate 31 and the bottom surface of the plate-like sample W through the cooling gas introduction hole 38.

A top surface 31a of the mounting plate 31 serves as an electrostatic adsorption surface which is mounted with a sheet of the plate-like sample W so as to electrostatically adsorb the plate-like sample W by means of an electrostatic adsorption force. The top surface (electrostatic adsorption surface) 31a is provided with a plurality of cylindrical protrusions (not shown) having a substantially circular section along the top surface 31a and the top surfaces of the protrusions are parallel to the top surface 31a.

A wall portion (not shown) that continuously extends along the peripheral portion and that has the same height as the protrusions so as not to leak the cooling gas such as He is formed in the peripheral portion of the top surface 31a so as to surround the peripheral portion of the top surface 31a circularly.

The electrostatic chuck device 21 having the above-mentioned configuration is placed in a chamber of a plasma processing apparatus such as a plasma etching apparatus, the plate-like sample W is mounted on the top surface 31a of the mounting surface, and then a variety of plasma processes can be performed on the plate like sample W by applying a high-frequency voltage across the metal base section 23 also serving as a high frequency generating electrode and the upper electrode to generate plasma on the mounting plate 31 while applying a predetermined DC voltage to the electrostatic-adsorption inner electrode 25 through the power supply terminal 27 to adsorb and fix the plate-like sample W by the use of an electrostatic force.

Next, the elements of the electrostatic chuck device will be described in more detail.

“Mounting Plate and Support Plate”

The mounting plate 31 and the support plate 32 are both made of ceramics.

Ceramics including one kind selected from or complex ceramics including two or more kinds selected from aluminum nitride (AlN), aluminum oxide (Al₂O₃), silicon nitride (Si₃N₄), zirconium oxide (ZrO₂), sialon, boron nitride (BN), and silicon carbide (SiC) can be preferably used as the ceramics.

The materials may be used alone or in combination. It is preferable that the thermal expansion coefficient thereof be as close as possible to that of the electrostatic-adsorption inner electrode 25 and that they can be easily sintered. Since the top surface 31a of the mounting plate 31 serves as an electrostatic adsorption surface, it is preferable that a material having a high dielectric constant and not providing impurities to the plate-like sample W be selected.

In consideration of the above description, the mounting plate 31 and the support plate 32 are made of a silicon carbide-aluminum oxide complex sintered body in which silicon carbide is contained substantially in the range of 1 wt % to 20 wt % and the balance is aluminum oxide.

When a complex sintered body including aluminum oxide (Al₂O₃) and silicon carbide (SiC) of which the surface is coated with silicon oxide (SiO₂) is used as the silicon carbide-aluminum oxide complex sintered body and the content of silicon carbide (SiC) is set to the range of 5 wt % to 15 wt % with respect to the entire complex sintered body, the volume resistivity at room temperature (25° C.) is 1.0×10¹⁴ Ωcm or more, and thus the complex sintered body is suitable for the mounting plate 31 of a coulomb type electrostatic chuck device. The complex sintered body is excellent in wear resistance, does not cause contamination of a wafer or generation of particles, and has enhanced plasma resistance.

When a complex sintered body including aluminum oxide (Al₂O₃) and silicon carbide (SiC) is used as the silicon carbide-aluminum oxide complex sintered body and the content of silicon carbide (SiC) is set to the range of 5 wt % to 15 wt % with respect to the entire complex sintered body, the volume resistivity thereof at room temperature (25° C.) is in the range of 1.0×10⁹ Ωcm to 1.0×10¹² Ωcm, and thus the complex sintered body is suitable for the mounting plate 31 of a Johnson-Rahbeck type electrostatic chuck device. The complex sintered body is excellent in wear resistance, does not cause contamination of a wafer or generation of particles, and has enhanced plasma resistance.

The average particle diameter of silicon carbide particles in the silicon carbide-aluminum oxide complex sintered body is preferably 0.2 μm or less.

When the average particle diameter of the silicon carbide particles is greater than 0.2 μm, the electric field at the time of application of the plasma is concentrated on portions of the silicon carbide particles in the silicon carbide-aluminum oxide complex sintered body, thereby easily damaging the peripheries of the silicon carbide particles.

The average particle diameter of the aluminum oxide particles in the silicon carbide-aluminum oxide complex sintered body is preferably 2 μm or less.

When the average particle diameter of the aluminum oxide particles is greater than 2 μm, the silicon carbide-aluminum oxide complex sintered body is easily etched by the plasma to form sputtering scars, thereby increasing the surface roughness.

“Electrostatic-Adsorption Inner Electrode”

The electrostatic-adsorption inner electrode 25 is formed of flat panel-shaped ceramics with a thickness in the range of about 10 μm to 50 μm and the volume resistivity at the usage temperature of the electrostatic chuck device is preferably in the range of 1.0×10⁻¹ Ωcm to 1.0×10⁸ Ωcm and more preferably in the range of 1.0×10² Ωcm to 1.0×10⁴ Ωcm.

Here, the reason for limiting the volume resistivity to the above-mentioned range is as follows. When the volume resistivity is less than 10×10⁻¹ Ωcm and a high-frequency voltage is applied to the metal base section 23, the high-frequency current does not pass through the electrostatic-adsorption inner electrode 25 and the electric field strength on the surface of the electrostatic chuck section 22 is not even, thereby not obtaining a uniform plasma. On the other hand, when the volume resistivity is greater than 1.0×10⁸ Ωcm, the electrostatic-adsorption inner electrode 25 substantially becomes an insulator and thus does not function as an electrostatic-adsorption inner electrode so as not to generate an electrostatic adsorption force, or the responsiveness of the electrostatic adsorption force is deteriorated and thus a long time is required for generating the necessary electrostatic adsorption force.

Examples of the ceramics constituting the electrostatic-adsorption inner electrode 25 include the following various complex sintered bodies:

(1) a complex sintered body in which semiconductor ceramics such as silicon carbide (SiC) are added to the insulating ceramics such as aluminum oxide;

(2) a complex sintered body in which conductive ceramics such as tantalum nitride (TaN), tantalum carbide (TaC), and molybdenum carbide (Mo₂C) are added to the insulating ceramics such as aluminum oxide;

(3) a complex sintered body in which a high melting-point metal such as molybdenum (Mo), tungsten (W), and tantalum (Ta) is added to the insulating ceramics such as aluminum oxide; and

(4) a complex sintered body in which a conductive material such as carbon (C) is added to the insulating ceramics such as aluminum oxide.

The volume resistivity of these materials can be easily controlled within the range of 1.0×10⁻¹ Ωcm to 1.0×10⁸ Ωcm by controlling the amount of conductive components added thereto. Specifically, when the mounting plate 31 and the support plate 32 are both made of ceramics, the thermal expansion coefficients of electrostatic-adsorption inner electrode 25 are close to those of the mounting plate 31 and the support plate 32, and thus the materials are very suitable as materials for forming the electrostatic-adsorption inner electrode 25.

The shape or size of the electrostatic-adsorption inner electrode 25 can be suitably adjusted. The entire area of the electrostatic-adsorption inner electrode 25 is not necessarily made of a material having a volume resistivity in the range of 1.0×10⁻¹ Ωcm to 1.0×10⁸ Ωcm. 50% or more of the entire area of the electrostatic-adsorption inner electrode 25 and preferably 70% or more thereof may be made of a material having a volume resistivity in the range of 1.0×10⁻¹ Ωcm to 1.0×10⁸ Ωcm.

“Insulating Layer”

The insulating layer 33 serves to bond the mounting plate 31 and the support plate 32 to each other to form a body and to protect the electrostatic-adsorption inner electrode 25 from plasma or corrosive gas. The insulating layer 33 is preferably made of an insulating material having the same main component as the mounting plate 31 and the support plate 32. For example, when the mounting plate 31 and the support plate 32 are formed of the silicon carbide-aluminum oxide complex sintered body, the insulating layer 33 is preferably made of aluminum oxide (Al₂O₃).

“Dielectric Plate”

The dielectric plate 24 is buried in the metal base section 23 so as to decrease the electric field strength at the center of the electrostatic chuck section 22. The electric field strength on the surface of the electrostatic chuck section 22 becomes more uniform when high-frequency power is applied to the metal base section 23. Accordingly, the plasma density becomes more uniform.

The dielectric plate 24 can be preferably formed of ceramics having excellent insulating characteristics and thermal conductivity and examples thereof include an aluminum oxide (Al₂O₃) sintered body and an aluminum nitride (AlN) sintered body.

The thickness of the dielectric plate 24 is preferably in the range of 2 mm to 15 mm and more preferably in the range of 4 mm to 8 mm.

When the thickness of the dielectric plate 24 is less than 2 mm, an effect sufficient for decreasing the electric field strength at the center of the electrostatic chuck section 22 is not obtained. On the other hand, when the thickness of the dielectric plate 24 is greater than 15 mm, the thermal conductivity from the metal base section 23 to the plate-like sample W is decreased, thereby making it difficult to keep the plate-like sample W at a desired constant temperature.

It is preferable that the thickness of the dielectric plate 24 decrease from the center to the peripheral edge.

By allowing the thickness of the dielectric plate 24 to decrease from the center to the peripheral edge, it is possible to further reduce the electric field strength at the center of the electrostatic chuck section 22 and to make the electric field strength on the surface of the electrostatic chuck section 22 more uniform when a high-frequency power is applied to the metal base section 23. Accordingly, it is possible to make the plasma density more even.

When the thickness of the dielectric plate 24 decreases from the center to the peripheral edge, the thickness may be concentrically and stepwise decreased to form a sectional step shape as shown in FIG. 2, or the thickness may be concentrically and gradually decreased to form a cone shape as shown in FIG. 3.

The insulating adhesive bonding layer 35 for adhesively bonding the dielectric plate 24 and the support plate 32 of the electrostatic chuck section 22 to each other is not particularly limited so long as it has excellent insulating characteristics. For example, a material obtained by adding aluminum nitride (AlN) powder or alumina (Al₂O₃) powder as insulating ceramics to a silicon-based adhesive is preferably used.

The reason for using the insulating adhesive bonding layer 35 is as follows. When the dielectric plate 24 and the support plate 32 are adhesively bonded to each other with a conductive adhesive bonding layer interposed therebetween, a high-frequency current does not flow through the conductive adhesive bonding layer, but flows toward the peripheral edge through the conductive adhesive bonding layer, thereby not obtaining a uniform plasma.

Here, the dielectric plate 24 is bonded and fixed to the concave portion 34 with the insulating adhesive bonding layer 35 or a conductive adhesive bonding layer interposed therebetween. However, the adhesive bonding portions of the dielectric plate 24 and the concave portion 34 are made to be complementary to each other, and thus the dielectric plate 24 and the concave portion 34 may be fitted to each other.

“Method of Manufacturing Electrostatic Chuck Device”

A method of manufacturing an electrostatic chuck device according to this embodiment will be described.

Described here is an example in which the mounting plate 31 and the support plate 32 are formed of the silicon carbide-aluminum oxide complex sintered body substantially containing silicon carbide in the range of 1 wt % to 20 wt %.

Silicon carbide powder having an average particle diameter of 0.1 μm or less is preferably used as the raw powder of silicon carbide (SiC).

The reason is as follows. When the average particle diameter of the silicon carbide (SiC) powder is greater than 0.1 μm, the average particle diameter of the silicon carbide particles in the obtained silicon carbide-aluminum oxide complex sintered body is greater than 0.2 μm, and thus the strength of the mounting plate 31 and the support plate 32 is not sufficiently enhanced.

When the mounting plate 31 formed of the silicon carbide-aluminum oxide complex sintered body is exposed to the plasma, the electric field is concentrated on the silicon carbide (SiC) particles to significantly damage the particles, whereby the plasma resistance may be reduced and the electrostatic adsorption force after the plasma damage may be reduced.

The powder obtained by a plasma CVD method is preferably used as the silicon carbide (SiC) powder. Specifically, a super fine powder having an average particle diameter of 0.1 μm or less, which is obtained by introducing raw gas of a silane compound or silicon halide and hydrocarbon into plasma in a non-oxidizing atmosphere and carrying out vapor phase reaction while controlling the pressure of the reaction system in the range of 1×10⁵ Pa (1 atm) to 1.33×10 Pa (0.1 Torr), has excellent sintering ability, high purity, and spherical particle shapes, and thus is excellent in dispersibility when this is formed.

On the other hand, aluminum oxide (Al₂O₃) powder having an average particle diameter of 1 μm or less is preferably used as the raw powder of aluminum oxide (Al₂O₃).

The reason is as follows. In the silicon carbide-aluminum oxide complex sintered body obtained using the aluminum oxide (Al₂O₃) powder having an average particle diameter larger than 1 μm, the average particle diameter of the aluminum oxide (Al₂O₃) particles in the complex sintered body is greater than 2 μm. Accordingly, the top surface 31a of the mounting plate 31 on which the plate-like sample is mounted can be easily etched by the plasma to form sputtering scars to increase the surface roughness of the top surface 31a, thereby deteriorating the electrostatic adsorption force of the electrostatic chuck device 21.

The aluminum oxide (Al₂O₃) powder is not particularly limited, so long as it has an average particle diameter of 1 μm or less and high purity.

Subsequently, the silicon carbide (SiC) powder and the aluminum oxide (Al₂O₃) powder are mixed at a ratio to obtain a desired volume resistivity value.

Then, the mixed powder is shaped into a predetermined shape by the use of a mold and the resultant shaped body is pressurized and baked, for example, by the use of a hot press (HP), thereby obtaining a silicon carbide-aluminum oxide complex sintered body.

The pressurizing force of hot press (HP) conditions is not particularly limited, but is preferably in the range of 5 to 40 MPa when it is intended to obtain the silicon carbide-aluminum oxide complex sintered body. When the pressurizing force is less than 5 MPa, it is not possible to obtain a complex sintered body with a sufficient sintering density. On the other hand, when the pressurizing force is greater than 40 MPa, a jig made of graphite or the like is deformed and worn.

The baking temperature is preferably in the range of 1650° C. to 1850° C. When the baking temperature is less than 1650° C., it is not possible to obtain a sufficiently dense silicon carbide-aluminum oxide complex sintered body. On the other hand, when the baking temperature is greater than 1850° C., decomposition or particle growth of the sintered body may easily occur in the course of baking the sintered body.

The baking atmosphere is preferably an inert gas atmosphere such as argon or nitrogen atmosphere for the purpose of preventing oxidation of silicon carbide.

A power supply terminal insertion hole 36 is mechanically formed at a predetermined position of one sheet of a complex sintered body of two sheets of the resultant silicon carbide-aluminum oxide complex sintered body, which is used as the support plate 32.

As a coating agent for forming the electrostatic-adsorption inner electrode, a coating agent, which is made into a paste by adding conductive material powder such as molybdenum carbide (Mo₂C) to insulating ceramic powder such as aluminum oxide (Al₂O₃) at such a ratio that the volume resistivity at the usage temperature of the electrostatic chuck device is in the range of 1.0×10⁻¹ Ωcm to 1.0×10⁸ Ωcm, is manufactured. The coating agent is applied to a region of the support plate 32 in which the electrostatic-adsorption inner electrode is formed, thereby forming a conductive layer. The coating agent made into a paste containing the insulating ceramic powder such as aluminum oxide (Al₂O₃) is applied to a region outside the region in which the conductive layer is formed, thereby forming an insulating layer.

Subsequently, the power supply terminal 27 is inserted into the power supply terminal insertion hole 36 of the support plate 32 with a cylindrical insulator 37 interposed therebetween, the surface of the support plate 32 on which the conductive layer and the insulating layer are formed is superposed on the mounting plate 31, the mounting plate 31 and the support plate 32 are heated and pressurized, for example, at a temperature of 1,600° C. or more, the electrostatic-adsorption inner electrode 25 and the insulating layer 33 as a bonding layer are formed of the conductive layer and the insulating layer, respectively, and then the mounting plate 31 and the support plate 32 are bonded to each other with the electrostatic-adsorption inner electrode 25 and the insulating layer 33 interposed therebetween. Then, the top surface 31a of the mounting plate 31 serving as a mounting surface is polished so that Ra (center-line average roughness) is 0.3 μm or less, thereby manufacturing the electrostatic chuck section 22.

On the other hand, the metal base section 23 in which a circular concave portion 34 is formed in the surface thereof and a flow passage 28 for circulating a cooling medium is formed therein is manufactured using an aluminum (Al) plate. The dielectric plate 24 is manufactured using an aluminum oxide sintered body by shaping and baking aluminum oxide (Al₂O₃) powder.

Subsequently, a insulating adhesive bonding agent is applied to the entire inner surface of the concave portion 34 of the metal base section 23, the dielectric plate 24 is adhesively bonded onto the insulating adhesive bonding agent, an insulating adhesive bonding agent is applied onto the metal base section 23 including the dielectric plate 24, and then the electrostatic chuck section 22 is adhesively bonded onto the insulating adhesive bonding agent.

In the adhesive bonding process, the dielectric plate 24 is bonded and fixed to the concave portion 34 of the metal base section 23 with the insulating adhesive bonding layer 35 interposed therebetween. The support plate 32 of the electrostatic chuck section 22 is bonded and fixed to the metal base section 23 and the dielectric plate 24 with the insulating adhesive bonding layer 35 interposed therebetween.

In this way, it is possible to obtain the electrostatic chuck device according to this embodiment.

As described above, in the electrostatic chuck device according to this embodiment, the electrostatic-adsorption inner electrode 25 is interposed between the mounting plate 31 and the support plate 32 and the volume resistivity of the electrostatic-adsorption inner electrode 25 at the usage temperature of the electrostatic chuck device is set to the range of 1.0×10⁻¹ Ωcm to 1.0×10⁸ Ωcm. Accordingly, when a high-frequency voltage is applied to the metal base section 23, the high-frequency current can flow through the electrostatic-adsorption inner electrode 25 and the electric field strength on the surface of the electrostatic chuck section 22 can be made even, thereby performing a uniform plasma process on the large-area plate-like sample W.

When the concave portion 34 is formed in the surface of the metal base section 23 facing the electrostatic chuck section 22, the dielectric plate 24 is fixed to the concave portion 34, and the dielectric plate 24 and the support plate 32 of the electrostatic chuck section 22 are adhesively bonded to each other with the insulating adhesive bonding layer 35 interposed therebetween, it is possible to further enhance the insulating characteristics between the metal base section 23 and the electrostatic chuck section 22. When the dielectric plate 24 is buried, it is possible to further reduce the electric field strength at the center of the electrostatic chuck section 22. Accordingly, it is possible to make more uniform the electric field strength on the surface of the electrostatic chuck section when the high-frequency voltage is applied to the metal base section 23, thereby making the plasma density more even.

When the thickness of the dielectric plate 24 decreases from the center to the peripheral edge, it is possible to further reduce the electric field strength at the center of the electrostatic chuck section 22 and thus to make more uniform the electric field strength on the surface of the electrostatic chuck section when a high-frequency voltage is applied to the metal base section 23, thereby further making the plasma density more even.

### Second Embodiment

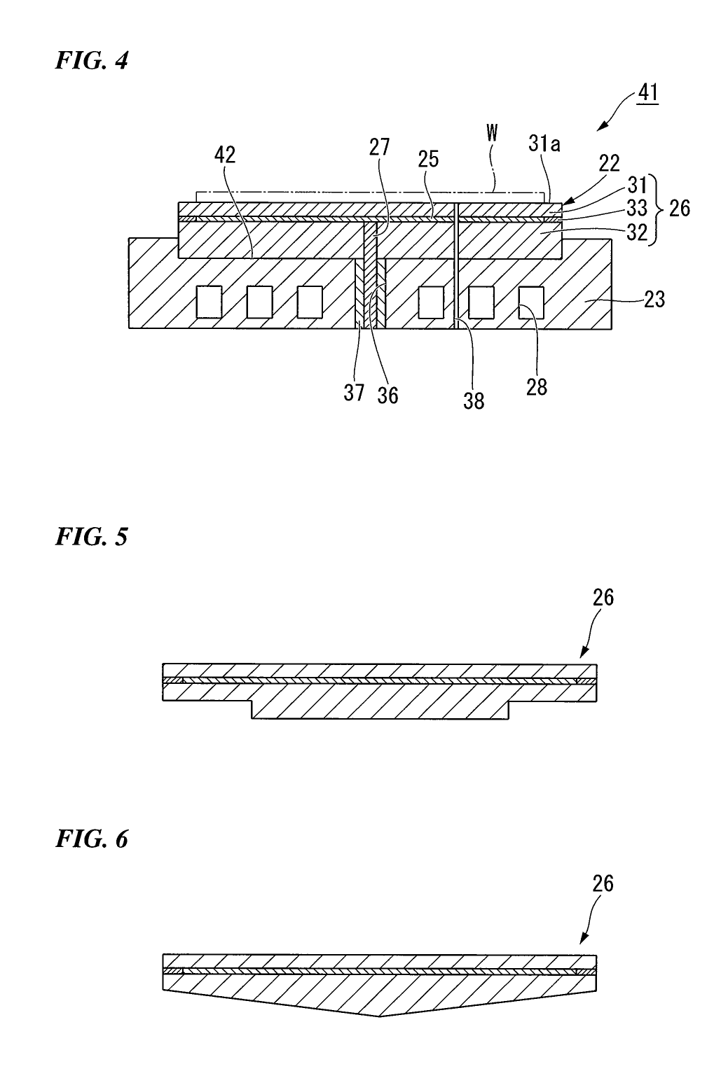

FIG. 4 is a sectional view illustrating an electrostatic chuck device 41 according to a second embodiment of the invention. The electrostatic chuck device 41 according to this embodiment is different from the electrostatic chuck device 21 according to the first embodiment, in that a concave portion 42 having the same shape as the bottom of the substrate 26 of the electrostatic chuck section 22 and having a depth smaller than the height of the electrostatic chuck section 22 is formed in the surface (main surface) of the metal base section 23 facing the electrostatic chuck section 22 and at least a part of the bottom of the substrate 26 of the electrostatic chuck section 22 is inserted into and fixed to the concave portion 42.

Here, at least a part of the bottom of the substrate 26 of the electrostatic chuck section 22 is inserted into and fixed to the concave portion 42, but they may be adhesively bonded to each other with an insulating adhesive bonding layer interposed therebetween, similarly to the electrostatic chuck device 21 according to the first embodiment.

It is preferable that the thickness of the substrate 26 of the electrostatic chuck section 22 decrease from the center thereof to the peripheral edge.

When the thickness of the substrate 26 decreases from the center to the peripheral edge, it is possible to further enhance the effect of reducing the electric field strength at the center of the electrostatic chuck section 22, and thus to make more uniform the electric field strength on the surface of the electrostatic chuck section 22 when a high-frequency voltage is applied to the metal base section 23. As a result, it is possible to make the plasma density more uniform.

When the thickness of the substrate 26 is decreased from the center to the peripheral edge, the thickness may concentrically and stepwise decrease so as to form a sectional step shape, for example, as shown in FIG. 5, or may concentrically and gradually decrease so as to form a cone shape, for example, as shown in FIG. 6.

In the electrostatic chuck device 41 according to this embodiment, it is possible to obtain the same advantages as the electrostatic chuck device 21 according to the first embodiment.

Specifically, since at least a part of the bottom of the substrate 26 of the electrostatic chuck section 22 is inserted into and fixed to the concave portion 42, it is possible to easily position and fix the electrostatic chuck section 22 and the metal base section 23 relative to each other.

### EXAMPLES

Hereinafter, the invention will be specifically described with reference to an example and comparative examples, but the invention is not limited to the examples.

### Example

The electrostatic chuck device shown in FIG. 1 was manufactured by the above-mentioned manufacturing method. However, the mounting plate 31 and the support plate 32 were both formed of the silicon carbide-aluminum oxide complex sintered body having a volume resistivity of 1.0×10¹⁵ Ωcm at room temperature (25° C.), a thickness of 0.5 mm, and a diameter of 298 mm. The electrostatic-adsorption inner electrode 25 had a disc shape and was formed of a molybdenum carbide-aluminum oxide complex sintered body having a volume resistivity of 5.0×10⁻¹ Ωcm at room temperature (25° C.) and a thickness of 12 μm and which contained 30 vol % of molybdenum carbide (Mo₂C), and the balance being aluminum oxide. However, the dielectric plate 24 was formed of the aluminum oxide sintered body having the shape shown in FIG. 3, a diameter of 239 mm, and a thickness of 6 mm at the center thereof.

On the other hand, the metal base section 23 was manufactured in which the concave portion 34 having a diameter of 240 mm and a center depth of 6.1 mm was formed at the center thereof out of aluminum metal and the flow passage 28 was formed therein.

The dielectric plate 24 was adhesively bonded and fixed to the concave portion 34 with the silicon-based insulating adhesive bonding agent containing an aluminum nitride (AlN) filler, and the dielectric plate 24 and the support plate 32 of the electrostatic chuck section 22 were adhesively bonded to each other with the same insulating adhesive bonding agent, thereby obtaining the electrostatic chuck device according to this embodiment.

“Evaluation”

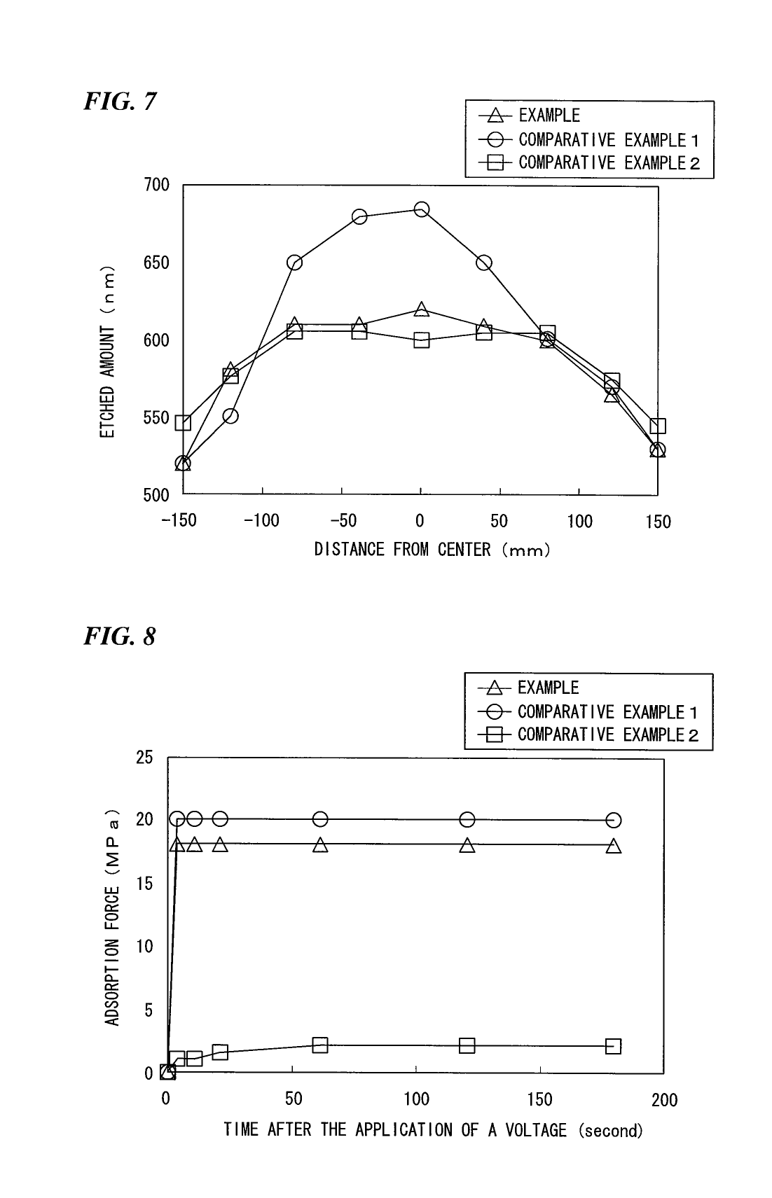

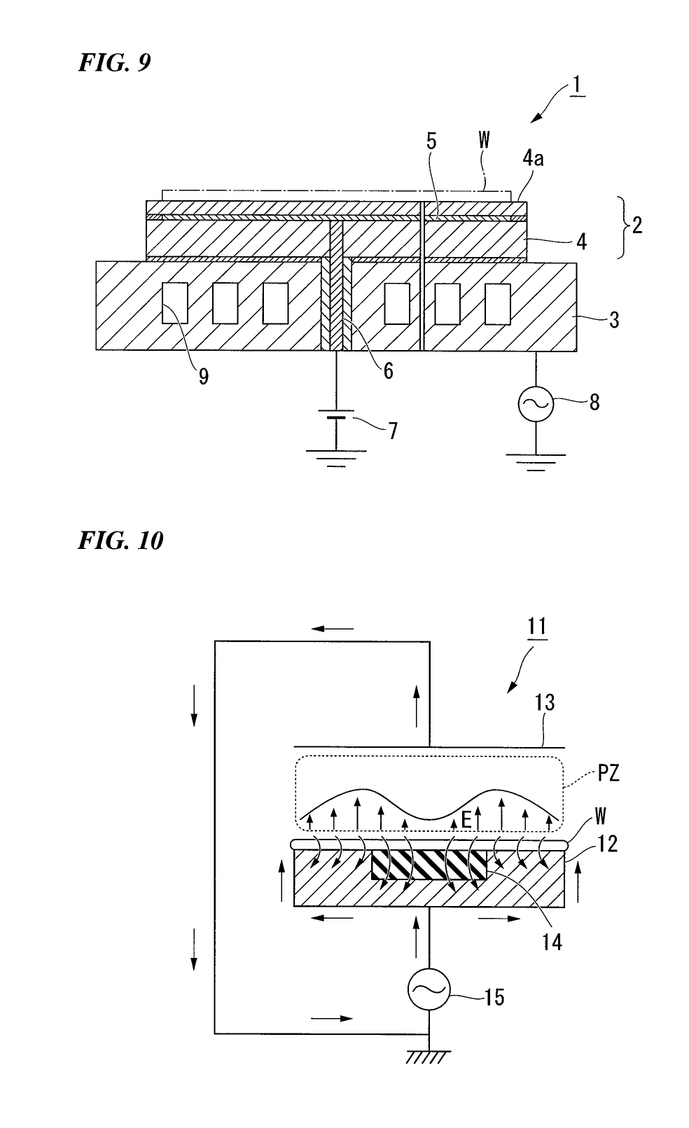

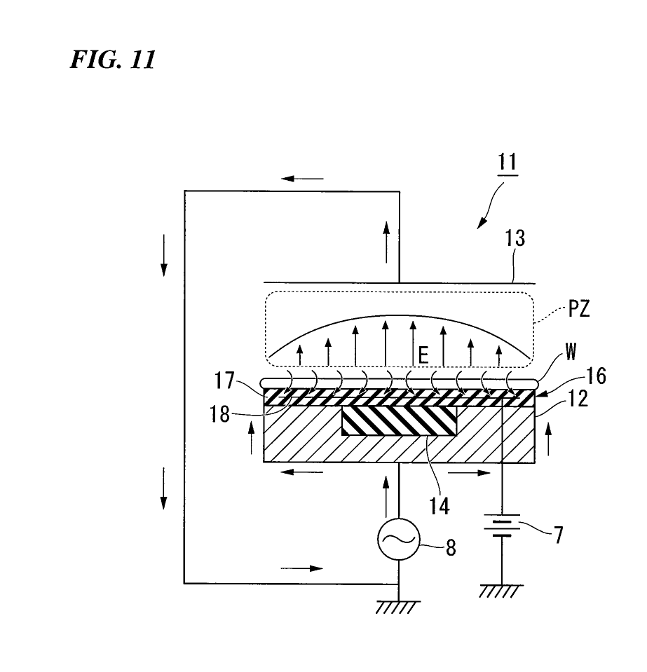

The plasma uniformity of the electrostatic chuck device according to this example was evaluated as described below. The variation with time of the electrostatic adsorption force (the responsiveness of the electrostatic adsorption force) at the time of applying a DC voltage of 2500 V to the power supply terminal was evaluated at room temperature (25° C.). The evaluation result of the plasma uniformity and the evaluation result of the variation with time of the electrostatic adsorption force are shown in FIGS. 7 and 8, respectively

“Method of Evaluating Plasma Uniformity”

The electrostatic chuck device of the example was mounted on a plasma etching apparatus, a wafer in which a resist film with a diameter of 300 mm (12 inch) was formed was placed as the plate-like sample on the mounting surface for the electrostatic chuck device, plasma was generated while the wafer was fixed by electrostatic adsorption resulting from an application of a DC voltage of 2500 V, and an ashing process of the resist film was performed at the temperature of 25° C. The processing chamber was pressurized using O₂ gas (100 sccm) at 0.7 Pa (5 mTorr), the high-frequency power for generating plasma had a frequency of 100 MHz and power of 2 kW, He gas with a predetermined pressure (15 Torr) was made to flow in the gap between the mounting plate 21 and the silicon wafer from the cooling gas introduction hole 38, and a coolant at 20° C. was made to flow in the flow passage 28 of the metal base section 23.

Then, the thickness of the resist film from the center of the wafer to the outer peripheral edge was measured to calculate the etched amount.

### Comparative Example 1

An electrostatic chuck device of Comparative Example 1 was manufactured similarly to the example, except that the electrostatic-adsorption inner electrode 25 was formed of a molybdenum carbide-aluminum oxide complex sintered body containing 35 vol % of molybdenum (Mo₂C) and the balance of aluminum oxide, and having a volume resistivity of 5.0×10⁻² Ωcm at room temperature (25° C.) and a thickness of 10 μm.

The plasma uniformity and the temporal variation in electrostatic adsorption force (the responsiveness of the electrostatic adsorption force) of the electrostatic chuck device of Comparative Example 1 were evaluated similarly to the example. The evaluation results are shown in FIGS. 7 and 8.

### Comparative Example 2

An electrostatic chuck device of Comparative Example 2 was manufactured similarly to the example, except that the electrostatic-adsorption inner electrode 25 was formed of a molybdenum carbide-aluminum oxide complex sintered body containing 25 vol % of molybdenum (Mo₂C) and the balance of aluminum oxide, and having a volume resistivity of 1.0×10⁹ Ωcm at room temperature (25° C.) and a thickness of 10 μm.

The plasma uniformity and the temporal variation in electrostatic adsorption force (the responsiveness of the electrostatic adsorption force) of the electrostatic chuck device of Comparative Example 2 were evaluated similarly to the example. The evaluation results are shown in FIGS. 7 and 8.

It could be seen from the evaluation results that the electrostatic chuck device of the example was excellent in plasma uniformity because the etched amount was substantially constant at the center and the peripheral edge of the wafer and was excellent in responsiveness of the electrostatic adsorption force because the electrostatic adsorption force was saturated immediately after the application of a voltage.

On the contrary, it could be seen that the electrostatic chuck device of Comparative Example 1 was excellent in responsiveness of the electrostatic adsorption force but poor in plasma uniformity because the etched amount was large at the center of the wafer and small at the peripheral edge.

It could be seen that the electrostatic chuck device of Comparative Example 2 was excellent in plasma uniformity because the etched amount was substantially constant at the center and the peripheral edge of the wafer, but poor in responsiveness of the electrostatic adsorption force.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An electrostatic chuck device comprising:
an electrostatic chuck section including a substrate, which has a main surface serving as a mounting surface on which a plate-like sample is mounted and an electrostatic-adsorption inner electrode built therein, and a power supply terminal for applying a DC voltage to the electrostatic-adsorption inner electrode; and
a metal base section that is fixed to the other main surface of the substrate of the electrostatic chuck section so as to be incorporated into a body and that serves as a high frequency generating electrode,
wherein the volume resistivity of the electrostatic-adsorption inner electrode is in the range of 1.0×10⁻¹ Ωcm to 1.0×10⁸ Ωcm.

2. An electrostatic chuck device according to claim 1, wherein a concave portion is formed in the main surface of the metal base section facing the electrostatic chuck section, a dielectric plate is fixed to the concave portion, and the dielectric plate and the electrostatic chuck section are adhesively bonded to each other with an insulating adhesive bonding layer interposed therebetween.

3. An electrostatic chuck device according to claim 2, wherein the thickness of the dielectric plate decreases from the center to the peripheral edge.

4. An electrostatic chuck device according to claim 1, wherein a concave portion is formed in the main surface of the metal base section facing the electrostatic chuck section and the substrate of the electrostatic chuck section is fixed to the concave portion.

5. An electrostatic chuck device according to claim 4, wherein the thickness of the substrate of the electrostatic chuck section decreases from the center to the peripheral edge.
